(19) United States
(12) Patent Application Publication
(10) Pub. No.: US 2025/0378890 A1
(43) Pub. Date: Dec. 11, 2025

(54) SYSTEMS AND METHODS FOR EXCERISE

(71) Applicant: BEACHBODY, LLC, El Segundo, CA (US)

(72) Inventors: Mohammed Iqbal, Santa Monica, CA (US); Herberto Calves, Santa Monica, CA (US)

(21) Appl. No.: 19/179,843

(22) Filed: Apr. 15, 2025

Related U.S. Application Data
(63) Continuation of application No. 18/616,433, filed on Mar. 26, 2024, now abandoned.
Application No. 18/616,433 is a continuation of application No. 17/865,327, filed on Jul. 14, 2022, now abandoned.
(60) Provisional application No. 63/221,886, filed on Jul. 14, 2021.

(51) Int. Cl. G11C 16/34; A63B 24/00; G11C 16/26

(52) U.S. Cl. CPC G11C 16/3404; A63B 24/0075; G11C 16/26; A63B 2024/0068; A63B 2024/0093; A63B 2220/836; A63B 2230/06

(57) ABSTRACT

Disclosed are example embodiments of an exercise system and methods for providing a personalized workout session. An example method for providing a personalized workout session includes collecting heart rate data of a user during a calibration workout session. The example method for providing a personalized workout session also includes determining a plurality of personalized heart rate zones for the user based on the collected heart rate data. Additionally, the example method for providing a personalized workout session includes providing, to an exercise equipment, a workout session having a plurality of workout segments, wherein each workout segment has a target heart rate zone that is associated with one of the plurality of personalized heart rate zones.

### CROSS-REFERENCE TO RELATED APPLICATIONS

The present application is a continuation of U.S. patent application Ser. No. 18/616,433, filed Mar. 26, 2024, which is a continuation of U.S. patent application Ser. No. 17/865,327, filed Jul. 14, 2022, now abandoned, which claims priority to U.S. Provisional Patent Application No. 63/221,866, filed Jul. 14, 2021, the disclosures of all of which are hereby incorporated by reference in their entireties.

### TECHNICAL FIELD

The disclosure relates generally to the field of exercise, and specifically and not by way of limitation, some embodiments are related to systems and methods for personalized workouts.

### BACKGROUND

The popularity of the stationary exercise machine (e.g., stationary bikes, treadmills), particularly the connected variety, has increased dramatically in recent years. Once considered too mundane, today's stationary exercise machine are interactive and fun due to, at least, the large selection of on-demand classes and social features. For example, people can now virtually bike with friends or take a simulated ride anywhere in the world. However, on-demand classes and simulations are generally designed and created for the masses, which lack any personalization. Accordingly, what is needed is a more personalized system and method for exercising.

### SUMMARY

In one example implementation, an embodiment includes systems and methods for providing a workout session having a plurality of workout segments. Each workout segment may have a target heart rate zone that is associated with one of a plurality of personalized heart rate zones.

Disclosed are example embodiments of a method for providing a personalized workout session. The method including collecting heart rate data of a user during a calibration workout session. The method also including determining a plurality of personalized heart rate zones for the user based on the collected heart rate data. Additionally, the method including providing, to an exercise equipment, a workout session having a plurality of workout segments, wherein each workout segment has a target heart rate zone that is associated with one of the plurality of personalized heart rate zones.

Disclosed are example embodiments of an exercise system. The exercise system includes a stationary bike having a crank sensor configured to determine a plurality of performance metrics. The exercise system also includes a memory. Additionally, the exercise system including one or more processors coupled to the memory. The one or more processors are configured to collect heart rate data while a user is performing a workout session. The one or more processors are also configured to determine the target heart rate zone based on the user's current workout segment within the workout session. Additionally, the one or more processors are configured to compare the user's current heart rate to the determined target heart rate zone. The one or more processors are also configured to adjust one or more operating parameter of the stationary bike based at least on the plurality of performance metrics from the crank sensor and the comparison of the user's current heart rate and the target heart rate zone. The one or more processors are also configured to deliver an instruction to the exercise equipment based at least on the comparison of the user's current heart rate and the target heart rate zone.

The features and advantages described in the specification are not all-inclusive. In particular, many additional features and advantages will be apparent to one of ordinary skill in the art in view of the drawings, specification, and claims. Moreover, it should be noted that the language used in the specification has been principally selected for readability and instructional purposes and may not have been selected to delineate or circumscribe the disclosed subject matter.

### BRIEF DESCRIPTION OF THE DRAWINGS

The foregoing summary, as well as the following detailed description, is better understood when read in conjunction with the accompanying drawings. The accompanying drawings, which are incorporated herein and form part of the specification, illustrate a plurality of embodiments and, together with the description, further serve to explain the principles involved and to enable a person skilled in the relevant art(s) to make and use the disclosed technologies.

FIG. 1 illustrates an example environment in which the invention is implemented.

FIG. 2 is a flow diagram that illustrates a process for determining personalized heart zones in accordance with some embodiments of the present disclosure.

FIG. 3 is a flow diagram that illustrates a process for personalizing a workout session in accordance with some embodiments of the present disclosure.

FIG. 4 is a flow diagram that illustrates a process for personalizing a workout session based on the user's performance in accordance with some embodiments of the present disclosure.

FIG. 5 illustrates an example display in accordance with some embodiments of the present disclosure.

FIG. 6 is a flow diagram that illustrates a process for dynamically changing a display based on the user's workout metrics in accordance with some embodiments of the present disclosure.

FIG. 7 illustrates an example display in accordance with some embodiments of the present disclosure.

FIG. 8 is a flow diagram that illustrates a process for personalizing a workout session based at least on data collected from the crank and the user in accordance with some embodiments of the present disclosure.

FIG. 9 is a flow diagram that illustrates a process for training an AI recommendation engine and a process for generating personalized workout plan using a pre-trained AI engine in accordance with some embodiments of the present disclosure.

FIG. 10 illustrates an example fitness system in accordance with some embodiments of the present disclosure.

FIG. 11 is a flow diagram illustrating an example method in accordance with some embodiments of the present disclosure.

FIG. 12 is a flow diagram illustrating an example method in accordance with some embodiments of the present disclosure.

The figures and the following description describe certain embodiments by way of illustration only. One skilled in the art will readily recognize from the following description that alternative embodiments of the structures and methods illustrated herein may be employed without departing from the principles described herein. Reference will now be made in detail to several embodiments, examples of which are illustrated in the accompanying figures. It is noted that wherever practicable similar or like reference numbers may be used in the figures to indicate similar or like functionality.

### DETAILED DESCRIPTION

The detailed description set forth below in connection with the appended drawings is intended as a description of configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

### Overview

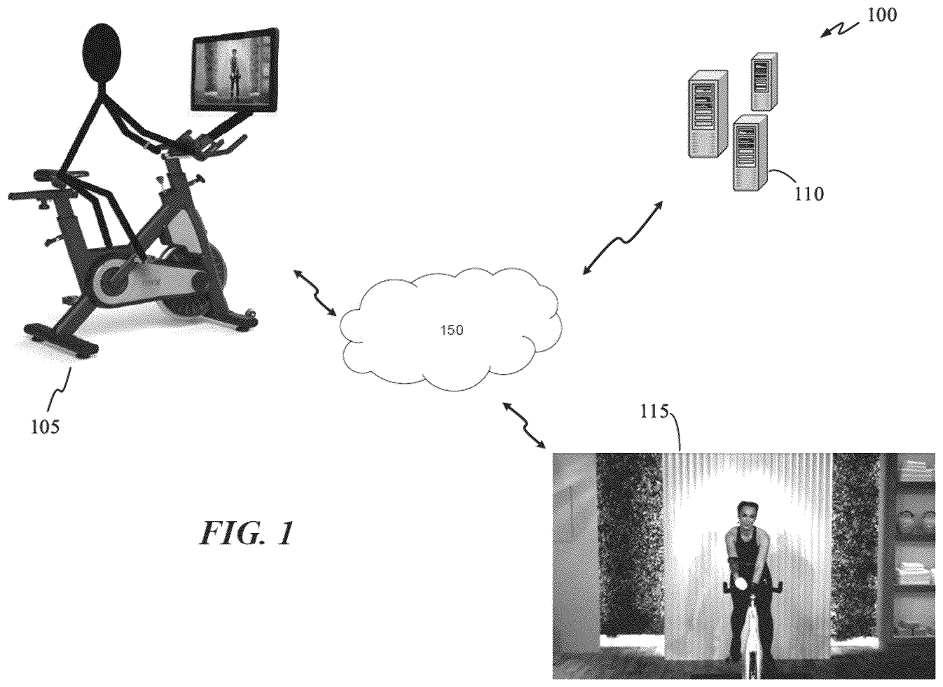

FIG. 1 illustrates an example exercise ecosystem 100 in which one or more of the inventions disclosed herein can be implemented. Ecosystem 100 includes one or more exercise machines 105, one or more remote servers 110, and one or more live sessions 115. Exercise machine 105 can be a home exercise machine such as, but not limited to, a treadmill, a rowing machine, or a stationary bike. Exercise machine 105 can a connected machine that is connected the internet 150 and/or to other local machines (not shown) via a local area network. Exercise machine 105 can also be connected to a plurality of other remote machines (not shown) and/or personal devices (e.g., heart rate monitor, power meter, sensors) over a local area network, internet 150, or other form of wireless communication such as, but not limited to, BlueTooth, WiFI, near-field communication (NFC). Exercise machine 105 can be communicatively connected to one or more servers 110, which can be online fitness services and/or full-service online exercise platforms. For example, platform 110 can be a subscription-based fitness service that provides recorded workout sessions, guided training programs, and instruction videos, etc. For instance, using exercise machine 105, a user can join a simulated bicycling session with a group of other users to bike anywhere in the world.

Exercise machine 105 can send data relating to the user to platform 110 for storage and analysis. For example, exercise machine 105 can send the following types of data to platform 110: heart rate data, crank sensor data (e.g., cadence, torque), machine operating parameters (e.g., resistance, inclination/declination data, roll), machine model No., user's personal data, GPS location, etc.

Platform 110 can also connect the user to live session 115 or an on-demand session (which can be a part of platform 110). For instance, the user can join a live workout cycling class hosted by an instructor. In some embodiments, platform 110 can collect and store users' data such as heart rate, workout history, exercising habits and preferences, favorite instructors, friends on platform 110, etc.

Platform 110 can include frontend services (not shown) such as, but not limited to, graphical user interfaces (GUIs), communication modules, and application programming interfaces (APIs) that enable exercise machine 105 to connect to platform 110. Platform 110 can also include backend services (not shown) such as, but not limited to, machine learning (ML) and/or artificial intelligence (AI) algorithms configured to analyze various types of data collected from machine 105 to provide personalized workout sessions, for example.

Exercise machine 105 can also include at least one processor that is capable of manipulating data in accordance with a set of instructions. For instance, the at least one processor of exercise machine 105 is configured to initiate communication with platform 110 to provide data to and/or request data from platform 110. For instance, exercise machine 105 can initiate a request to platform 110 to stream a recorded class, join a live class, search and chat with friends that are currently logged on platform 110, etc. Exercise machine 105 can receive and execute instructions from platform 110. For instance, during a workout session, the instructor may provide instructions to the user to increase cadence, increase resistance, or adjust inclination/roll. The user may perform the given instructions manually. In some embodiments, platform 110 can send the same instructions directly to exercise machine 110 to automatically adjust one of the machine operating parameters such as, but not limited to, changing the resistance, the incline, or the tilt (roll) of the machine. Exercise machine can also send real-time user's data and/or machine operating parameter data to platform 110 to enhance the user's experience. For instance, platform 110 can adjust workout session in real-time based on the received user's data. Platform 110 can also automatically adjust one or more operating parameters of exercise machine 105 such as, but not limited to, soundtrack being played, resistance, onboard lights, and the media content of the display/tablet of exercise machine 105. Media content can include scenic ride, augment reality ride, and others content where the movement and content can be dynamically adjusted based on the users' activity.

### Personalized Heart Zones

One of the biggest drawbacks of online fitness classes is that they are not personalized. Online fitness classes are generally designed for the mass without taking individual user's abilities and conditions into account. For instance, workout classes are generally made for beginner, intermediate, or expert. Workout classes can be easy, medium, or difficult. There is no existing fitness platform that offers workout sessions (e.g., classes) that are personalized to an individual based on the user's need and level of skills and experiences. Ecosystem 100 of the present disclosure is designed to do exactly that. Exercise machine 105 and/or platform 110 is configured to provide users personalized workout sessions based on the user's workout data and/or personal profile, which can include the user's heart rate data, blood pressure data, height, weight, age, level of experiences, favorite workout sessions, favorite instructor, etc. In some embodiments, workout sessions provided by ecosystem 100 are personalized based at least on the user's heart data. More specifically, workout sessions provided by ecosystem 100 can be based on the heart rate zones, which are determined and personalized based on the person's age and/or measured ability.

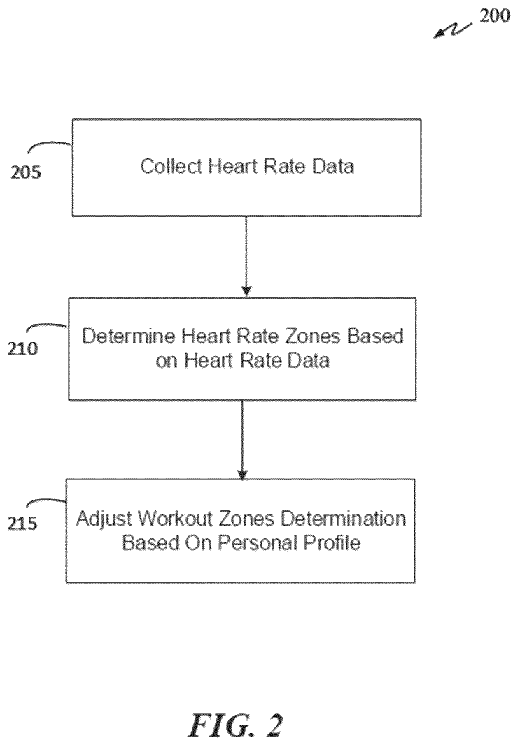

FIG. 2 illustrates a heart zones determination process 200 in accordance with some embodiments of the present disclosure. Process 200 starts at step 205 where heart rate data are collected from a user during an initial calibration ride, which is a ride to assess the user's ability and baselines heart rates at various workout intensities. Heart rate data can be collected using a palm sensor located on exercise machine 105. Alternatively, heart rate data can be collected using a wearable device such as a smartwatch with a built-in heart rate sensor and wireless communication capability. The user's wearable device can be paired with exercise machine 105, which enables data exchanges to occur between the wearable device and exercise machine 105.

To determine a user's personalized heart rate zones at step 210, the user is asked to complete a calibration workout session. For example, exercise machine 105 can be a stationary bike. In this case, the calibration workout session is a calibration ride designed to have various levels of intensity in order to obtain heart rate readings at various stages of the calibration ride. For instance, the calibration ride can have the following stages: warm up, low intensity, medium intensity, high intensity, and warm down. A heart rate profile can be obtained for one or more of these calibration stages. Additionally, at step 210, the user's personalized hear rate zones can be determined based at least on standard chart if the user cannot perform or complete the calibration workout session.

In some embodiments, three different heart rate profiles are determined: baseline heart rate, maximum heart rate, and recovery heart rate. The baseline heart rate is the lowest heart rate recorded during one of the stages of the calibration ride, which can be the warmup or low intensity stage. Alternatively, the baseline heart rate can be an average of heart rates measured during the warmup or low intensity stage. The maximum heart rate, as the name implies, is the maximum heart rate recorded during a high intensity stage of the calibration ride. The maximum heart rate can also be an average of recorded heart rates during the high intensity workout stage. The recovery heart rate is a heart rate taken after 1 minute from when the maximum heart rate is measured.

Step 210 determines the heart rate zones for each person based at least on the maximum detected heart rate during the calibration ride, which is designed to accurately and safely push the user to sustain a certain level of intensity so that the maximum heart rate can be measured. In some embodiments, step 210 will create three personalized heart zones for the user based on the measured heart rate. In some embodiments, step 210 can create three or more personalized heart zones such as 4, 5, or 10. But to simplify the user's experience, three heart zones are used.

In some embodiments, the three heart zones created by step 210 are zone 1, zone 2, and zone 3. Zone 1 is the low heart rate zone. Zone 2 is the medium heart rate zone, and zone 3 is the high heart rate zone. Zone 1 can have a heart rate range between 50-70% of the maximum heart rate. Zone 2 can have a heart rate range between 70-85% of the maximum heart rate. Zone 3 can have a heart rate range between 85-100% of the maximum heart rate. For example, if the user maximum recorded heart rate during the calibration ride is 194 beats per minute (BPM), then the three personalized heart rate zones for the user are as shown in the table I below.

TABLE I

| Zone | % Range | BPM |
|---|---|---|
| 1 | 50-70% | 97-135 |
| 2 | 70-85% | 136-164 |
| 3 | 85-100% | 165-194 |

Using the heart rate zones generated above, any workout session can now be modified and in effect personalized to individual user by assigning a heart rate zone to a specific segment of the workout session. For example, in a new workout session of ecosystem 100, rather instructing users to adjust the stationary bike inclination to a 10% incline, the instructor can instead encourage user to adjust the cadence, inclination, and/or resistance so that the user reaches the target zone 3. For user A, zone 3 can have a heart rate range of 165-194 BPM. However, for user B, zone 3 can have a heart rate range of 172-205 BPM. In this way, any workout session (e.g., recorded videos, live sessions) of ecosystem 100 can be personalized to any individual user. Each workout session can have the 3 different heart rate zones assigned to various segments of the workout session. Each of the three heart rate zones can also repeat and/or appear in order within the workout session.

In another example, the instructor can instruct users to move to zone 2 or zone 1. Metadata provided in a workout video (e.g., recorded workout session, live workout session) can include heart rate zone data synchronized to the instructor's shoutout or to specific segment(s) of the workout video. The heart rate zone data of the metadata of the workout video can include instructions for the exercise machine 105 to display certain information on the display of exercise machine 105 and/or to perform a certain machine operation (e.g., adjust resistance, adjust inclination). In this way, exercise machine 105 can display visual information such as, but not limited to, current heart rate zone, target heart rate zone, and upcoming target heart rate zone(s) in response to receiving the metadata, which can be extracted from the workout video or can be separately sent by platform 110. It should be noted that the workout metadata can also be in some other forms of data (it does not have to be metadata). In some embodiments, exercise machine 105 can also automatically adjust one or more operating parameters based on the received instructions and/or metadata from platform 110.

Environmental Control & Personalized Programs

Exercise machine 105 can also be paired with a local area hub (e.g., Google Nest, Alexa) that connects various devices throughout the home to the internet over WiFi. In this way, platform 110 can control various home devices such as, but not limited to, connected lights, connected speakers (e.g., Alexa speaker, Apple Homepod), and other smart home appliances (e.g., blender, coffee maker, refrigerator). For instance, during a workout session, platform 110 can control the music and/or lights (via the exercise machine 105) of the user's workout room to create a certain mood or to enhance the user experiences. Additionally, the user can use the local area hub (e.g., Alexa) to schedule a class, ask about live classes for a particular day (e.g., today), reschedule or pause a class.

In some embodiments, platform 110 can generate a personalized fitness program based on the user's profile, which can include heart rate data. A fitness program can include a fitness plan, a series of workout sessions, personalized nutritional information and recommendation, meal plans, etc. Alternatively, the user can also select a fitness program from many available workout programs on platform 110.

Platform 110 can automatically deliver a portion of the personalized fitness program to the user's personal devices (e.g., mobile phone, tablet) and/or exercise machine 105 on a set schedule. For example, platform 110 can deliver a daily meal plan on the user's mobile phone or connected refrigerator. The meal plan can include information such as recommended breakfast, lunch, and dinner menus, recipes, etc. For instance, after a workout session, platform 110 (or exercise machine 105) can send a reminder to the user's mobile device (e.g., smart watch) or refrigerator to drink an energy/recovery shake. Additionally, based on the use's fitness program, platform 110 can send the user's recommendation for lunch/dinner that would help the user to meet her fitness goals.

In some embodiments, platform 110 can make a meal recommendation based on the current user's geographical location and/or workout history data (e.g., daily calories burned, completed workout sessions). Using GPS location data from the user's mobile phone, platform 110 can find a nearby restaurant that serves the type of food as required by the user's personalized fitness program.

### Heart Zone Adjustment Factor

Referring again to process 200 of FIG. 2, at step 215, the three heart zones can further be personalized using an adjustment factor. In some embodiments, the adjustment factor for each user can be based on one or more criteria such as age, health condition, disability, level of experiences, etc. The adjustment factor can either decrease or increase the BPM range for each of the three zones. For example, the user's personal profile can indicate that the user has a health issue such as a bad foot or other medical issues. In response to this information, the personalized heart rate zone can be adjusted by an adjustment factor such as by reducing the range of each zone by a percentage. For example, the adjustment factor can adjust the range of BPM for each zone by 2%, 5%, 10%, or 15%. The adjustment factor can adjust the range of BPM downward or upward.

Alternatively, in response to the user's condition, a different workout can be suggested to the user. For example, if the user has a medical issue, an easier workout session can be recommended.

For example, the table II below illustrates an adjustment factor of −5%. Based on data in the user's profile, the user BPM range for each zone is adjusted downward by 5%. Again, the adjustment factor can be based on one or more of the following: age, level of experiences, health condition(s), past performances, etc.

TABLE II

| | | Original | Adjustment | Adjusted |
|---|---|---|---|---|
| Zone | % Range | BPM | Factor | BPM |
| 1 | 50-70% | 97-135 | −5.0% | 92-128 |
| 2 | 70-85% | 136-164 | −5.0% | 129-156 |
| 3 | 85-100% | 165-194 | −5.0% | 157-184 |

In another example, if the user have successfully completed many workout sessions on ecosystem 100 and have met all of the heart rate zone requirements in one or more workout sessions, then the adjustment factor can elevate the BPM range for each zone by 2-25%. For instance, the user's workout session history can indicate that the user's heart rate generally stays on the low side of the heart rate range zone 3 and rarely comes close to the maximum heart rate of zone 3. In this example, step 215 can adjust the user's heart rate zone to a higher range by applying a positive heart rate adjustment factor. In this way, the workout sessions can be continuously modified to push the user to higher fitness goals.

Each zone can have a range difference of 10-40%. For example, zone 1 can have a range between 40-65% of the maximum heart rate, which is a 25% difference. Zone 2 can have a range between 65-85%, which is a 20% difference.

In some embodiments, the heart rate zones can also be determined based on at least the user's age and the heart rate zone table below (Table III).

TABLE III

| | Zone 1 | | Zone 2 | | Zone 3 | |
|---|---|---|---|---|---|---|
| Age | 50% | 70% | 70% | 85% | 85% | 100% |
| 20 | 97 | 135 | 136 | 164 | 165 | 194 |
| 25 | 95 | 132 | 133 | 161 | 162 | 190 |
| 30 | 94 | 130 | 131 | 158 | 159 | 187 |
| 35 | 92 | 127 | 128 | 155 | 156 | 183 |
| 40 | 90 | 125 | 126 | 152 | 153 | 180 |
| 45 | 89 | 123 | 124 | 149 | 150 | 177 |
| 50 | 87 | 120 | 121 | 146 | 147 | 173 |
| 55 | 85 | 118 | 119 | 144 | 145 | 170 |
| 60 | 84 | 116 | 117 | 141 | 142 | 167 |
| 65 | 82 | 113 | 114 | 138 | 139 | 163 |
| 70 | 80 | 111 | 112 | 135 | 136 | 160 |
| 75 | 79 | 109 | 110 | 132 | 133 | 157 |
| 80 | 77 | 106 | 107 | 129 | 130 | 153 |

For example, if the user is 30 years old, the user's default heart rate zones are (according to table III): Zone 1, 94-130 BPM; Zone 2, 131-158 BPM; and Zone 3, 159-187 BPM. Table III can be used to select the heart rates zone for a user based on the user's age. Table III can also be use as the default heart rate zones if the calibration workout is unsuccessful. For example, if the user did not perform the calibration workout correctly or if the heart rate sensor failed, then a default heart rate zones can be used.

### Calibration Workout Run Using Wearables

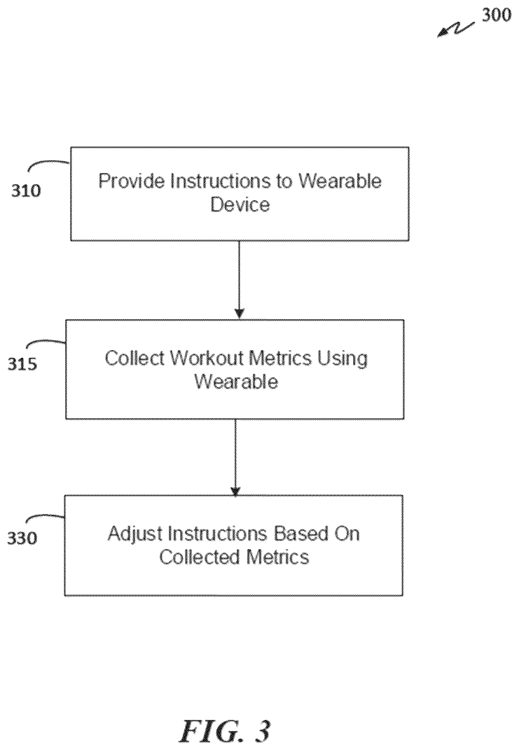

FIG. 3 illustrates heart zone calibration process 300 in accordance with some embodiments of the present disclosure. At step 310, exercise machine 105 can provide instructions to the user's wearable device such as a smartwatch or a wearable heart sensor. The instructions can cause the wearable to start or stop monitoring and/or sending the user's heart data to exercise machine 105. Once the calibration workout has started, the user's heart data can be collected by the wearable device. The heart rate data can be temporary stored on the wearable device. The heart rate data can also be transmitted to exercise machine 105 in real-time, which can then process and/or forward the data to platform 110. A calibration workout can be a workout session on a bike, treadmill, or using non-machine exercises (e.g., pushups, jumping jacks).

At 330, based on the collected heart rate data and metadata of the calibration workout, exercise machine 105 can adjust the instructions sent to the user. The instructions can be in visual, audio, haptic, or a combination thereof. The instructions can be based on the user's current heart rate and the target heart rate as specified in the metadata of the calibration workout. For example, the calibration workout can have 3 segments, a warmup segment, a medium intensity segment, and a high intensity segment designed to measure the maximum heart rate of the user. During the high intensity segment, the user should have a higher peak and average heart rate than the medium intensity segment. If, however, the measured heart rate during the high intensity segment is generally the same as the medium intensity segment, exercise machine 105 can send instructions to the wearable device to instruct the user to go faster via haptic feedback and/or audio instructions. In another example, if the measured heart rate during the medium intensity segment is generally the same or higher than the high intensity segment, exercise machine 105 can send instructions to the wearable device to instruct the user to go slower using haptic feedback and/or audio instructions.

In some embodiments, the wearable device can continuously provide haptic feedback during the calibration workout. For example, during the warmup segment of the calibration workout, the wearable device can provide a slow and steady vibration (or other form of haptic feedback) for the entire duration of the warmup segment. During the medium intensity segment of the calibration workout, the wearable device can provide a medium paced vibration for the entire duration of the medium intensity segment. During the high intensity segment of the calibration workout, the wearable device can provide a fast paced vibration for the entire duration of the high intensity segment. In this way, the wearable device (via exercise machine 105) can continuously direct the user to go faster or slower.

Although process 300 is called a “calibration” process, process 300 can be applied to any workout that goes through a prescribed assessment flow. In other words, process 300 can be used for non-calibration workout sessions to monitor and assess the users through various stages of the workout session.

### Guided Workout Session Using Heart Rate Zones

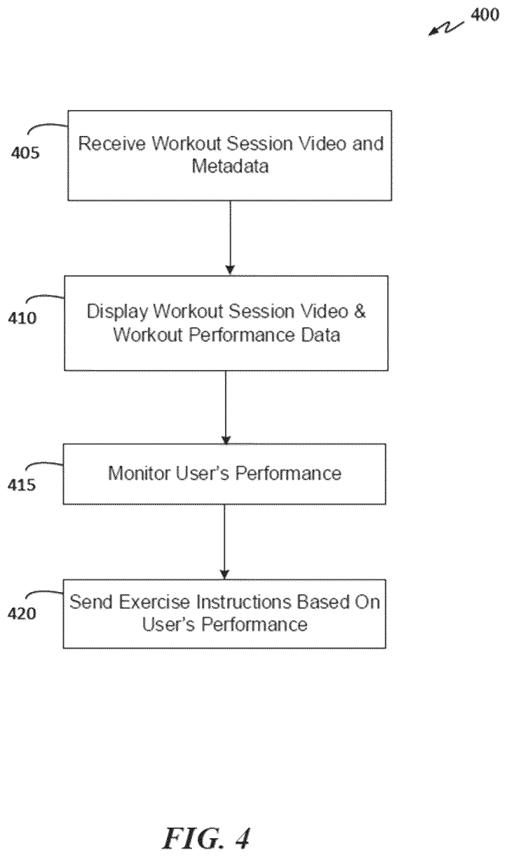

FIG. 4 illustrates a process 400 for providing a guided workout session based on at least heart rate zones in accordance with some embodiments of the present disclosure. Process 400 starts at 405 where a workout session video and metadata are received by exercise machine 105. The metadata can include heart rate zone information for a plurality of segments of the workout session. For example, a workout sessions can be a 30-minute workout having at least 3 segments such as, but not limited to, a warmup, cardio or fat burning, and a cool down session. Each segment can be associated with a plurality specific heart rate zones. At 410, the video of the workout session is displayed on a display of exercise machine 105. Some of the segment metadata can also be displayed to the user such as, but not limited to, the target heart rate zone, the next target heart rate zone or the target heart rate zone of the next workout segment, the average heart rate of other users in the same group as the user for the same workout segment. At 415, the heart rate of the user is continuously monitored during the workout session. The user's current heart rate can also be compared to the target heart rate zone. For example, a visual comparison of the current and target heart rates can be displayed.

At 420, the exercise instructions can be generated based on at least the user's current heart rate and the metadata (e.g., target heart rate zone) for one of the segments of the workout session. For example, if the user's current heart rate is far below the target heart rate, an instruction telling the user to go faster or to increase the resistance can be presented to the user. The instruction can be presented by exercise machine 105 in a form of a video, image and/or audio. The instruction can also be sent to the wearable device for presentation to the user, which can present the instruction to the user using audio and/or haptic feedback. At 420, the exercise instruction can be an instruction to change the operating parameter of exercise machine 105. For example, the instruction can instruct the user to change the resistance manually. Alternatively, the instruction can cause machine 105 to automatically adjust one or more of the exercise machine's operating parameters. For instance, the instruction can cause machine 105 to automatically adjust the resistance of exercise machine 105. The instruction can also cause exercise machine 105 to automatically adjust the inclination of exercise machine 105. Once the user's heart rate is at the target zone, further instructions can be sent to exercise machine 105 to instruct the user to slow down and maintain a certain pace. Further instructions can also be sent to exercise machine 105 to adjust one or more of the exercise machine's operating parameters so that the user's heart rate is maintained at a certain rate.

### Confirmation of Automatic Adjustment of Operating Parameters

Prior to automatically adjusting one or more operating parameters of exercise machine 105, a confirmation request can be presented to the user. Based on the user's response to the confirmation request, exercise machine 105 can adjust or abandon any adjustment of one or more operating parameters of exercise machine 105. For example, exercise machine 105 can present the following announcement and/or instructions to the user: i) the resistance and/or inclination will increase in 30 seconds; ii) to accept the increase in resistance and/or inclination, keep running/pedaling at the same pace; and 3 iii) to decline the automatic increase in resistance and/or inclination, the user can pedal slower, pedal at different speeds, or in the case of a treadmill run at different strides. In this way, the user can confirm or decline any automatic adjustment of one or more operating parameters by briefly changing a measurable exercising characteristic (e.g., speed, stride, jump). The user can also confirm using a verbal response or tapping on the wearable device. For instance, a single tap is to confirm the change and a double tap is to decline the change.

### Dynamic Display

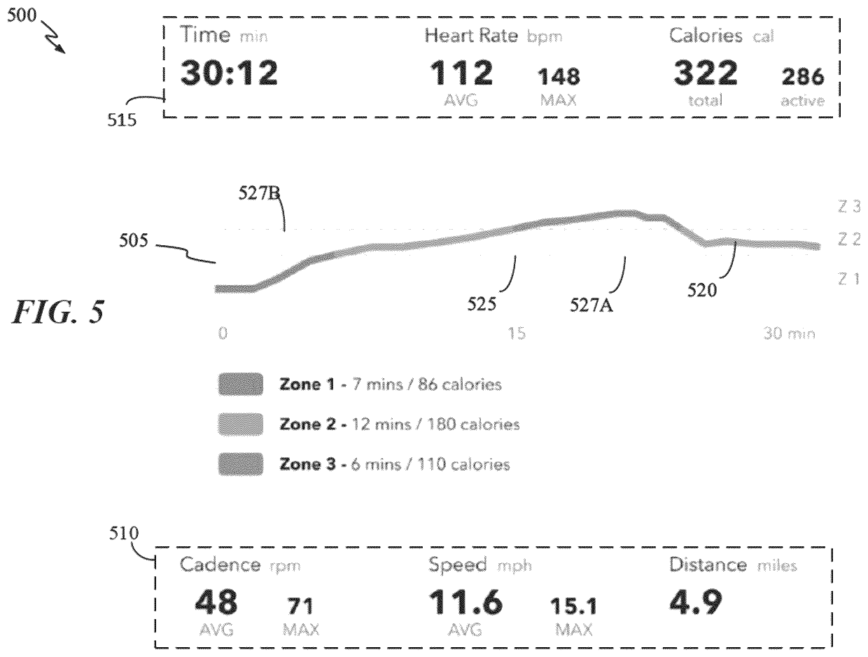

FIG. 5 illustrates a dynamic display 500 in accordance with some embodiments of the present disclosure. Dynamic display 500 can be graphical user interface (GUI) having one or more interactive features. Display 500 includes a chart 505 and one or more performance statistic regions 510 and 515. Chart 505 can include a heart rate line 520 to show the current heart rate (far right) as well as recorded heart rate at various times of a workout session, including beginning of the workout session at time zero. Heart rate line 520 can be updated in real-time as the workout session progresses. Chart 505 can also include a target heart rate zone indicator 525, which can have a minimum heart rate line 527A and a maximum heart rate line 527B. Heart rate zone indicator 525 is configured to move and refreshed based on the metadata of each workout segment of the workout session. As previously mentioned, the metadata of each workout segment can define the target heart rate zone, which is a range with a minimum and maximum value for the range.

During a workout session, heart rate zone indicator 525 can move to the target heart rate zone as indicated by the metadata of the workout session. For example, from time 0-9 minutes, the target heart rate zone is zone 1. Thus, during the first minutes of chart 505, heart rate zone indicator 525 is displayed lower on chart 505 to cover zone 1. And from 9-15 minutes, heart rate zone indicator 525 is moved to cover zone 2. As the user progresses along the workout session, hear rate line 520 continues to add new heart rate data points, which is displayed along with heart rate zone indicator 525. In this way, the user knows exactly where her heart rate is with respect to the target zone.

Heart rate line 520 can also change color based on whether the current heart rate is on target, lower, or higher than the current target heart rate zone. For example, heart rate line 520 can be green if the user's current heart rate is within range. Red can mean that the user's current heart rate exceeds the target zone. Blue or yellow can mean that the user's current heart rate is below the target zone. This adds another layer of visual instructions to the user, which enables the user to quickly determine her performance at a glance.

Audio and haptic feedback (e.g., vibrations, motions) can also be used to inform the user of her current performance (e.g., heart rate) with respect to the target heart rate zone. For example, exercise machine 105 can send instructions to the wearable device to provide haptic feedback during a workout session. For example, if the user's current heart rate is within the target zone, the wearable device can provide a slow and steady vibration (or other form of feedback) to indicate that the user is on track. If the user's current heart rate is below the target zone, the wearable device can provide two or more quick haptic bursts to inform the user to go faster, the haptic feedback can be repeated until the user comply and adjust her performance accordingly.

As stated, display 500 can include one or more performance statistic regions and 510 and 515. In some embodiments, regions 510 and 515 can be combined or can be further segmented. Each of the statistic regions 510 and 515 can display various performance statistics such as, but not limited to, exercise duration, current heart rate, average heart rate, maximum heart rate, total calories burned, duration in each heart rate zone, current cadence, average cadence, maximum cadence, current speed, average speed, maximum speed, total distance traveled, current heart rate zone, target heart rate zone, the target heart rate zone of the next workout segment, countdown to next workout segment, and countdown to the completion of the current workout session.

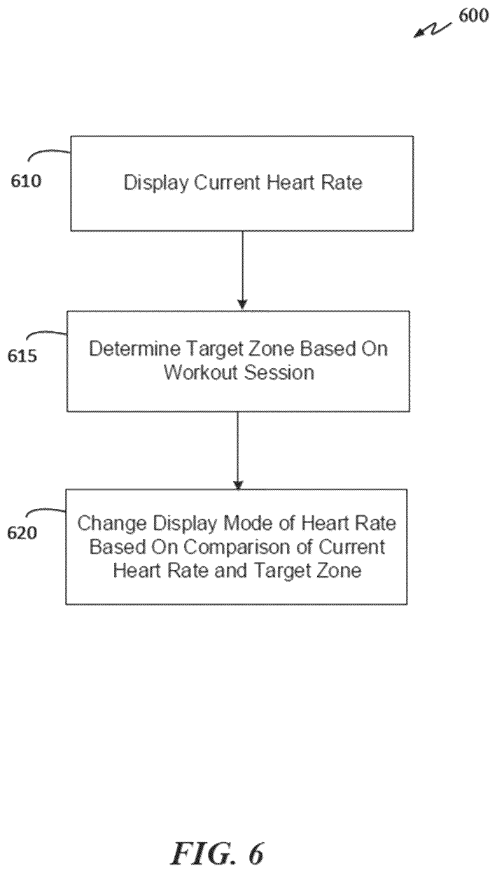

FIG. 6 illustrates a process 600 for dynamically displaying heart rate zone information in accordance with some embodiments of the present disclosure. Process 600 starts at 610 where the user's current heart rate is displayed on a display of exercise machine 105. For example, exercise machine 105 can include a monitor that shows display 500, that can display various performance statistics such as heart rate. At 615, the target heart rate zone is determined based on the metadata of the user's selected workout session. Each workout session can include metadata for a plurality of workout segments. The metadata can include one or more target heart rate zones for each workout segment. The user's target heart rate zone can be based on the heart zones determination process 200. Alternatively, the user's target heart rate zone can be solely on the user's age.

At 620, one or more characteristics of display 500 can be changed based on a comparison of the user's current heart rate and the target heart rate zone. For example, the color, line thickness, line pattern, or a combination thereof of heart rate line 520 can be changed dynamically and in real-time based on the comparison. For instance, heart rate line 520 can be green if the user's current heart rate is within the target heart rate zone. Heart rate line 520 can be red when the user's current heart rate exceeds the target heart rate zone, and so forth.

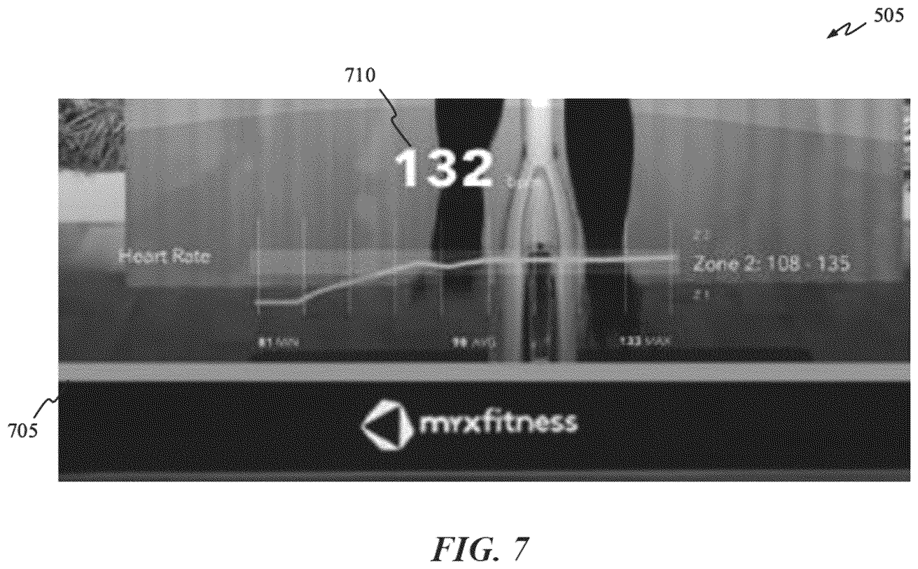

FIG. 7 illustrates chart 505 being displayed as a transparent overlay in accordance with some embodiments of the present disclosure. Chart 505 can be a transparent chart that can be displayed simultaneously with the video of the workout session. In this way, chart 505 does not significantly block the background image of the workout session. Chart 505 can include a color instruction bar 705 located near the bottom of the display. In some embodiments, instruction bar 705 can provide a visual guidance to the user by displaying one or more colors, texts, image, or a combination thereof. For example, as shown in FIG. 7, the current target heart rate zone is zone 2, which has a heart rate range of 108-135. The user's current heart rate is 132, see item 710. Since the user's current heart rate is within the target heart rate zone, the instruction bar 705 can show the color green indicating that the user's is on track or doing well. It should be noted that other colors can be used other than green to indicate that the user is doing well such as, but not limited to, orange, purple, white, and pink. Regardless of the color used, a consistent color scheme to indicate how well the user is doing should be adopted. For instance, the following color scheme can be adopted:
Green—On track, maintain current performance;
Red—Too fast, lower intensity or slow down; and
Blue—Too slow, increase intensity or speed up.

In some embodiments, instruction bar 705 can also pulsate to help the user maintain her pace. For example, a medium-paced pulsation or no pulsation can indicate that the user is on track and to maintain the current performance. A fast-paced pulsation can indicate that the user is going too slow and should increase the intensity until the fast-paced pulsation stop. A slow-paced pulsation can indicate the user is going too fast and should decrease the intensity until the slow-paced pulsation stop. Other pulsation patterns can be used to provide different instructions. For

### Integrated Crank Sensor Data

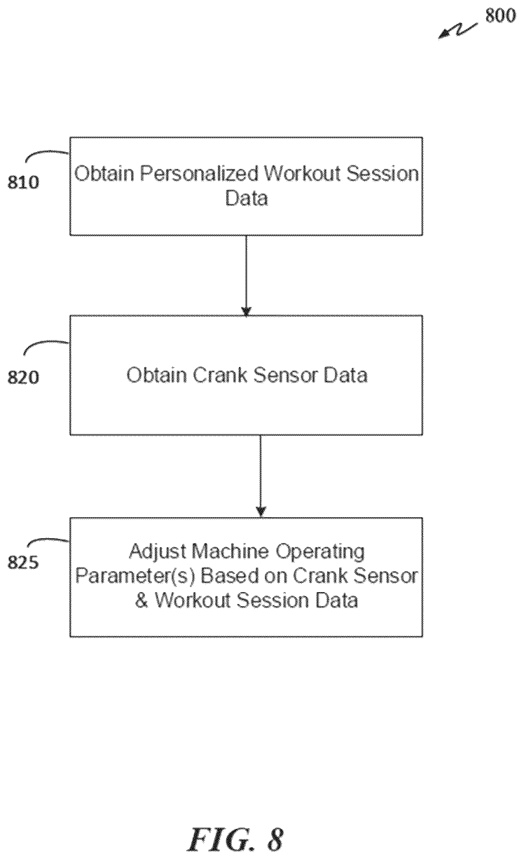

FIG. 8 illustrates a process 800 for providing a personalized workout session using integrated crank sensor data. Process 800 starts at 810 where the user's personalized workout session is retrieved from platform 110. For example, step 810 can retrieve the user's heart rate zones for each workout session as described in process 200. The user's personalized heart rate zones can also be modified using an adjustment factor as described in step 215 of process 200. During a workout session, the crank sensor data can be collected and analyzed at step 820. The crank sensor data can include cadence and torque, which can be used to compute the amount of power being produced by the user while exercising on a stationary bike. The crank sensor data are generated by one or more sensors disposed in a cavity of the crank of a stationary exercise bike. The one or more sensors can be a strain gage configured to measure the force being applied on the crank and an accelerometer, which is configured to measure the rotation per minute or cadence.

Power can then be measured based on the measured force and cadence using the following Equations:

$$Power = Torque \times Cadence \qquad Eqn . 1$$

$$Cadence = R \times 0.147 \qquad Eqn . 2$$

$$Torque = {F}_{avg} \times 9.8 \times L \qquad Eqn . 3$$

In equation 2, R is the rotation. In equation 3, F_{avg} is the average force over one revolution. L is the length of the crank, and 9.8 is the gravitational constant. Using the collected crank sensor data and the above equations, the power generated by the user can be computed. It should be noted that one or more constants in one or more of the above equations can change based on a configuration of the machine such as, but not limited to, the crank's length.

At step 825, the user's current heart rate is compared it with the target heart rate zone of a workout segment. Based on this comparison or in combination with other metadata such as, but not limited to, the remaining time of the workout segment, process 800 can provide instructions to the user to perform a task. For example, if the user's current heart rate is well below the target heart zone, process 800 can instruct the user to pedal faster. Additionally, using the equation 2, the process 800 can instruct the user's to increase the pedaling rate to a predetermined rotation per minute. For instance, process 800 can instruct the user to increase the pedaling speed by 15%. Then as the user approaches the targeted RPM, the instructions (which can be audio or visual) can actively change from 15% to 10%, 5%, etc.

Additionally, at step 825, one or more operating parameters of exercise machine 105 can be automatically adjusted based on the comparison of the user's current heart rate and the metadata of the workout session. For example, the resistance and/or inclination of exercise machine 105 can automatically be changed, which can affect the force and/or the RPM. For instance, lowering the resistance can help increase the RPM and ultimately the cadence and power.

### Personalized & Smart (AI-Based) Recommendation

Often times, when starting an exercise routine, the user is faced with a flood of workout choices. For example, there are numerous type of exercises the user can select from such as Pilates, yoga, bodyweight, running, biking, etc. There are also numerous of other factors for the user to consider such as instructors, level of difficulties, duration of a workout session, target heart rate zones, workout release date, ratings of each workout session, etc. All of these choices are good for the users. However, they can also be overwhelming and eventually become too much for the user to manage on a regular basis. This can lead to user's frustration or worst can cause the user to quit entirely because finding and selecting a workout session can become a laborious chore. As such what is needed is a smart recommendation system that will take most (if not all) of the guess work away from the user and delegate the guess work to an artificial intelligence (AI) recommendation system. In this way, the user can maximally enjoy the plentitude of workout offerings of platform 110 without having to think of all the choices.

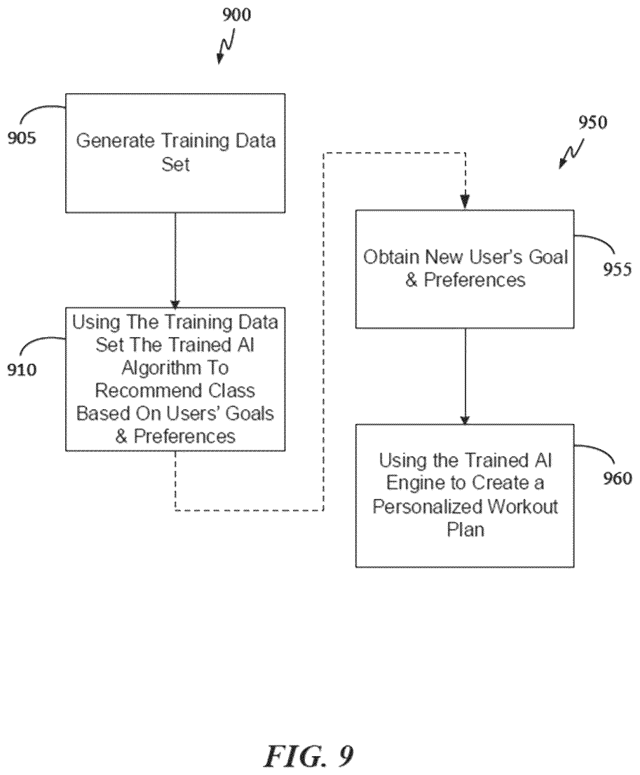

FIG. 9 illustrates a training process 900 for training an artificial intelligence (AI) engine to generate personalized recommendations for workout and a process 950 for generating personalized workout recommendations using the pre-trained AI engine. Each of processes 900 and 950 can be separately implemented. However, process 950 is dependent upon the trained-AI engine created in training process 900. The end goal of processes 900 and 950 is to make the user's exercise habits automatic, hassle-free, and enjoyable.

Training process 900 starts at 905 where a training data set is generated. The training data set can include data points for hundreds or thousands of workout sessions. The data points collected for each workout session can include categories such as, but not limited to, video freshness indicator, duration of workout session, workout category, workout type, total number of people started the workout session, total number of people completed the workout session, total number of people used a heart rate monitor during the workout session, total number of people using the heart rate monitor for the entirety of the workout session, times the workout session is favorited, number of unique user favorited the workout session, number of stars ratings for the workout session, average users' rating, percent of people completed the workout session, percentage of people completed the workout session while wearing a heart rate monitor, instructor ratings, difficulty rating of the workout session, and overall score.

The video freshness indicator indicates when the video was released. The video freshness indicator can also be based on how many times the user has taken the class and/or how many times the class has been recommended to the user. For example, the freshness indicator can be the number of days since the release of the video. The freshness indicator can also be based on the number of times the session has been recommended to the user and/or taken by the user. Thus, the highest freshness score is 1. The lowest freshness score, theoretically, has no limit since it can be years since the workout session was released and/or the user has completed the course numerous times. But practically the lowest freshness score can be limited to 5 years. This essentially means no workout session on platform 110 is over 5 years old.

The workout category can be floor training, biking, cross-training, mindful training, weight training, etc. The workout type can be yoga, barre, kettlebells, cardio sculpt, dance cardio, foam rolling, climb ride, rhythm ride, HIIT, ride+tone, meditation, stretching, theme ride, total body sculpt, etc.

The total number of people started each workout session, and the total number of people completed each workout session provide the percentage of people that completed the workout session. This statistic along with the difficulty rating, number of stars ratings, and/or number of unique user favorited can indicate the overall popularity of the workout session, which can be part of the overall score of the workout session.

The star rating includes a 1 through 5 star rating for each workout session. Although other range can be used (e.g., 1-10). For each workout session, the number of 1-star, 2-star, 3-star, 4-star, and 5-star ratings will be recorded. 5 is the highest rating, and 1 is the lowest rating.

The training data set can also include users' workout preferences and goals. Workout preferences can include preferred workout category (e.g., bike, cross-training, running, floor) and preferred workout type (e.g., kettlebells, ride & tone, kickboxing, core, yoga). Other user's preferences can include difficulty or average difficulty of workout session, duration of each workout session, instructors, number of workout times per week, total number of workout hours per week, etc. The user's goals can be weight lost, toning, muscle development, endurance training, etc.

The training data set can also include the user's personal profile, which can include information such as gender, age, diet, height, weight, body-to-mass index, and health history.

The training data set can also include ideal workout programs for hypothetical and/or real users. The training data set can also include hundreds or thousands of workout programs.

At 910, using an AI-engine, one or more relationships and patterns between a plurality of workout sessions and user's preferences and goals can be established from the training data set. This AI-determined relationships and patterns can then be used to generate new workout programs given a workout goal and preferences of a new user. Additionally, at 910, the AI-engine can: (1) consume or digest external data sources to provide AI driven recommendations. For example, the user might have gone running using another application, thus the AI-engine can recommend a stretching session when it recognizes that the user has just finished the running session. (2) Provide AI based recommendations for nutrition and supplement plans. The AI-engine can be fed data from outside sources such as blood tests to provide personalized recommendations. In addition, based on what has worked or preferred for other users of the same cohort, we can drive AI based recommendations.

This leads to process 950, which is configured to create a personalized workout program based on one or more of the user's goal and preferences. At 955, the fitness goal(s) and exercise preferences are collected from the user. For example, the user can define the goal as improving endurance. The user can also indicate that she would like to workout 3 times a week for a total of 3 hours. Finally, the user can also indicate that she does not like running exercises. Given the above user's goal and workout preferences, the trained AI-engine can create a workout plan for one or more days or an entire week at 960.

In some embodiments, the user can select and replace one or more of the recommended workout sessions in the AI-generated workout plan. Based on the replacement, the AI-engine can recalculate and adjust the workout plan for the remainder of the week or for another week. For example, if one of the recommended courses has high heart rate zones requirements, the users can select an easier course to replace the more difficult default workout course. In this embodiment, process 950 can recalculate a portion or the entirety of the workout plan for the week or month. In this way, the user can have total control over workout schedule.

FIG. 9 illustrates an overall system or apparatus 900 in which machine 105, platform 110, display 500, and processes 200, 300, 400, 600 and 800 can be implemented. In accordance with various aspects of the disclosure, an element, or any portion of an element, or any combination of elements may be implemented with a processing system 914 that includes one or more processing circuits 904. Processing circuits 904 may include micro-processing circuits, microcontrollers, digital signal processing circuits (DSPs), field programmable gate arrays (FPGAs), programmable logic devices (PLDs), state machines, gated logic, discrete hardware circuits, and other suitable hardware configured to perform the various functionality described throughout this disclosure. That is, the processing circuit 904 may be used to implement any one or more of the processes and graphical user interfaces described above and illustrated in FIGS. 1 through 8.

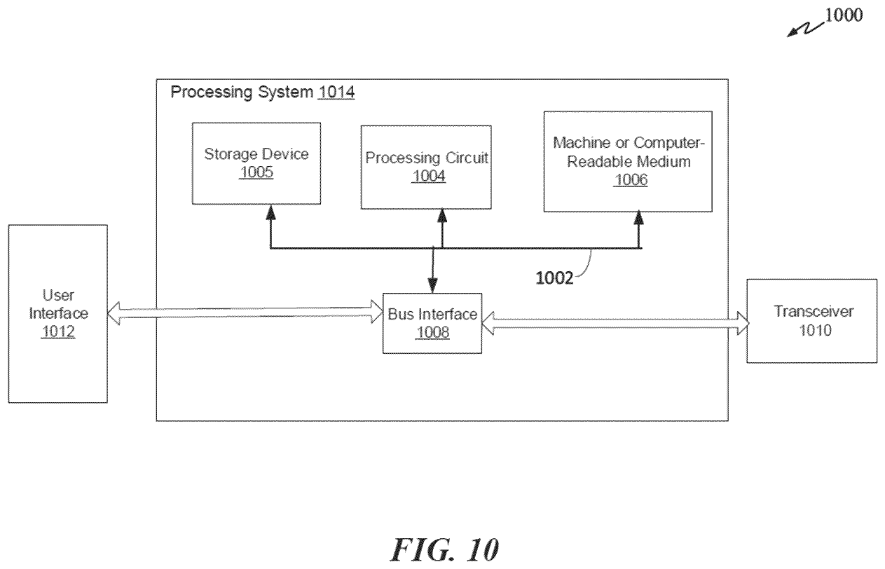

In the example of FIG. 10, the processing system 1014 may be implemented with a bus architecture, represented generally by the bus 1002. The bus 1002 may include any number of interconnecting buses and bridges depending on the specific application of the processing system 1014 and the overall design constraints. The bus 1002 links various circuits including one or more processing circuits (represented generally by the processing circuit 1004), the storage device 1005, and a machine-readable, processor-readable, processing circuit-readable or computer-readable media (represented generally by a non-transitory machine-readable medium 1006.) The bus 1002 may also link various other circuits such as timing sources, peripherals, voltage regulators, and power management circuits, which are well known in the art, and therefore, will not be described any further. The bus interface 1008 provides an interface between bus 1002 and a transceiver 1010. The transceiver 1010 provides a means for communicating with various other apparatus over a transmission medium. Depending upon the nature of the apparatus, a user interface 1012 (e.g., keypad, display, speaker, microphone, touchscreen, motion sensor) may also be provided.

The processing circuit 1004 is responsible for managing the bus 1002 and for general processing, including the execution of software stored on the machine-readable medium 1006. The software, when executed by processing circuit 1004, causes processing system 1014 to perform the various functions described herein for any particular apparatus. Machine-readable medium 1006 may also be used for storing data that is manipulated by processing circuit 1004 when executing software.

One or more processing circuits 1004 (e.g., microprocessors) in the processing system may execute software or software components. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. A processing circuit may perform the tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory or storage contents. Information, arguments, parameters, data, etc. may be passed, forwarded, or transmitted via any suitable means including memory sharing, message passing, token passing, network transmission, etc.

The software may reside on machine-readable medium 1006. The machine-readable medium 1006 may be a non-transitory machine-readable medium. A non-transitory processing circuit-readable, machine-readable or computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), RAM, ROM, a programmable ROM (PROM), an erasable PROM (EPROM), an electrically erasable PROM (EEPROM), a register, a removable disk, a hard disk, a CD-ROM and any other suitable medium for storing software and/or instructions that may be accessed and read by a machine or computer. The terms “machine-readable medium”, “computer-readable medium”, “processing circuit-readable medium” and/or “processor-readable medium” may include, but are not limited to, non-transitory media such as portable or fixed storage devices, optical storage devices, and various other media capable of storing, containing or carrying instruction(s) and/or data. Thus, the various methods described herein may be fully or partially implemented by instructions and/or data that may be stored in a “machine-readable medium,” “computer-readable medium,” “processing circuit-readable medium” and/or “processor-readable medium” and executed by one or more processing circuits, machines and/or devices. The machine-readable medium may also include, by way of example, a carrier wave, a transmission line, and any other suitable medium for transmitting software and/or instructions that may be accessed and read by a computer.

The machine-readable medium 1006 may reside in the processing system 1014, external to the processing system 1014, or distributed across multiple entities including the processing system 1014. The machine-readable medium 1006 may be embodied in a computer program product. By way of example, a computer program product may include a machine-readable medium in packaging materials. Those skilled in the art will recognize how best to implement the described functionality presented throughout this disclosure depending on the particular application and the overall design constraints imposed on the overall system.

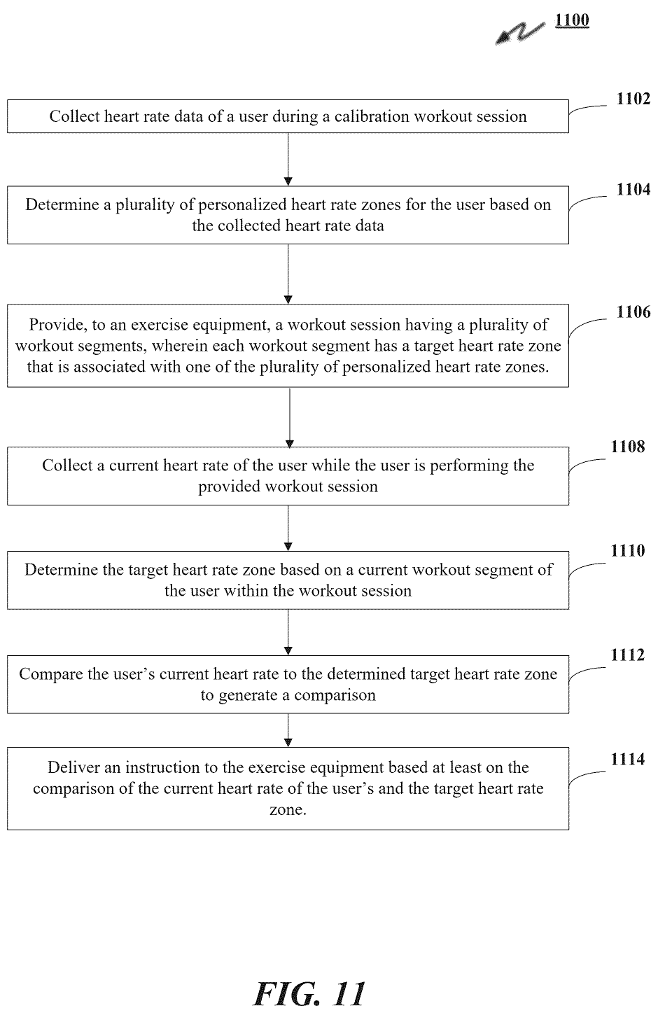

FIG. 11 is a flow diagram illustrating an example method 1100 in accordance with some embodiments of the present disclosure. The example method 1100 may be a method for providing a personalized workout session. The method 1100 may include collecting heart rate data of a user during a calibration workout session 1102. collecting heart rate data of a user during a calibration workout session may include measuring the heartrate of the user and storing that data for further processing. The method 1100 may also include determining a plurality of personalized heart rate zones for the user based on the collected heart rate data 1104. Determining a plurality of personalized heart rate zones for the user based on the collected heart rate data may include processing the heart rate data along with other data such as age, sex, and/or any medical conditions to determining a plurality of personalized heart rate zones. Additionally, the method 1100 may include providing, to an exercise equipment, a workout session having a plurality of workout segments, wherein each workout segment has a target heart rate zone that is associated with one of the plurality of personalized heart rate zones 1106. Providing the workout session may include generating a workout that may be estimated to result in one or more particular heartrate zones being entered by a person completing the workout, e.g., based on the desired heartrate zone or zones based on medical information for the user. The method 1100 may also include collecting heart rate data including using a wearable device having a heart rate sensor to collect the user's heart rate data 1108. In an example, the workout session may include a pre-recorded workout video or a live-stream of a workout session.

The method 1100 may include collecting a current heart rate of the user while the user is performing the provided workout session 1108. The method 1100 may also include determining the target heart rate zone based on a current workout segment of the user within the workout session 1110. Additionally, the method 1100 may include comparing the user's current heart rate to the determined target heart rate zone to generate a comparison. The method 1100 may also include delivering an instruction to the exercise equipment based at least on the comparison of the current heart rate of the user's and the target heart rate zone.

In an example, the instruction may be instructions requesting the user to change one or more operating parameters of the exercise equipment. In another example, the instruction may be instruction to the exercise equipment to automatically change one or more operating parameters of the exercise equipment. The one or more operating parameters may be an operating parameter selected from a group consisting of resistance, inclination, tilt, and playback audio.

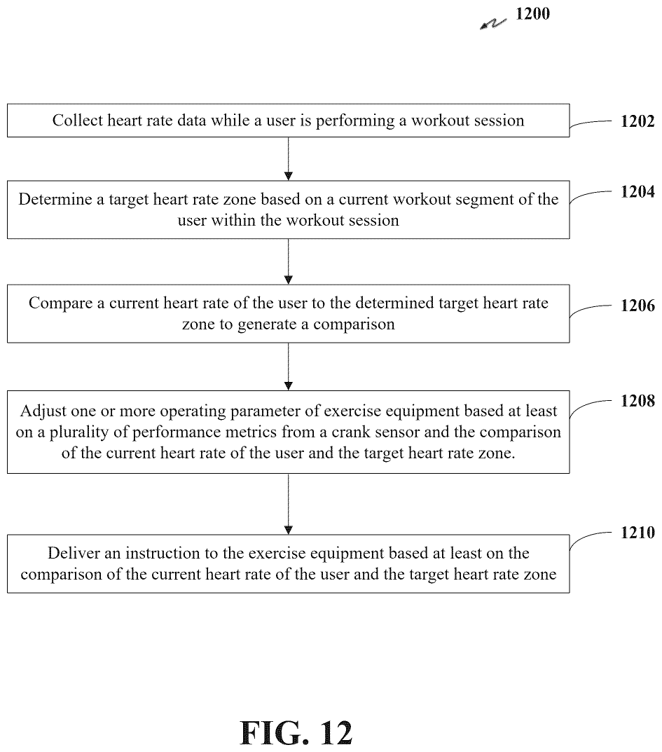

FIG. 12 is a flow diagram illustrating an example method 1200 in accordance with some embodiments of the present disclosure. The method 1200 may be a method for providing a personalized workout session. The method may include collect heart rate data while a user is performing a workout session 1202. Collect heart rate data may include measuring a user's heartrate and storing the heartrate data. The method may also include determine a target heart rate zone based on a current workout segment of the user within the workout session 1204. Determine a target heart rate zone may include determining what portion of a workout a user is in and determining a desired heartrate for that current workout segment. Additionally, the method may include comparing a current heart rate of the user to the determined target heart rate zone to generate a comparison 1206. Comparing a current heart rate of the user to the determined target heart rate zone may include processing the data for the current heart rate of the user and the determined target heart rate zone to generate a comparison of the two (or more) values. The method may also include adjusting one or more operating parameter of exercise equipment based at least on a plurality of performance metrics from a crank sensor and the comparison of the current heart rate of the user and the target heart rate zone 1208. Adjusting one or more operating parameter of exercise equipment may include making the equipment more or less taxing for the user based on the performance metrics from a crank sensor and the comparison of the current heart rate of the user and the target heart rate zone. Additionally, the method may include delivering an instruction to the exercise equipment based at least on the comparison of the current heart rate of the user and the target heart rate zone 1210. Delivering an instruction to the exercise equipment may include generating or selecting an instruction and transmitting the instruction to the exercise equipment.

Adjusting one or more operating parameter of the exercise equipment may include presenting instructions to the user to change one or more operating parameters of the exercise equipment. Adjusting one or more operating parameter of the exercise equipment may include automatically adjusting one or more operating parameters of the exercise equipment. The one or more operating parameters may include an operating parameter selected from a group consisting of resistance, inclination, tilt, and playback audio. Collecting heart rate data may include using a wearable device having a heart rate sensor to collect the user's heart rate data. The workout session may include a pre-recorded workout video or a live-stream of a workout session.

+One or more of the components, steps, features, and/or functions illustrated in the figures may be rearranged and/or combined into a single component, block, feature or function or embodied in several components, steps, or functions. Additional elements, components, steps, and/or functions may also be added without departing from the disclosure. The apparatus, devices, and/or components illustrated in the Figures may be configured to perform one or more of the methods, features, or steps described in the Figures. The algorithms described herein may also be efficiently implemented in software and/or embedded in hardware.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the following detailed description are presented in terms of algorithms and symbolic representations of operations on data bits within a computer memory. These algorithmic descriptions and representations are the methods used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared or otherwise manipulated. It has proven convenient at times, principally for reasons of common usage, to refer to these signals as bits, values, elements, symbols, characters, terms, numbers or the like.

It should be borne in mind, however, that all of these and similar terms are to be associated with the appropriate physical quantities and are merely convenient labels applied to these quantities. Unless specifically stated otherwise as apparent from the following disclosure, it is appreciated that throughout the disclosure terms such as “processing,” “computing,” “calculating,” “determining,” “displaying” or the like, refer to the action and processes of a computer system, or similar electronic computing device, that manipulates and transforms data represented as physical (electronic) quantities within the computer system's registers and memories into other data similarly represented as physical quantities within the computer system's memories or registers or other such information storage, transmission or display.

Finally, the algorithms and displays presented herein are not inherently related to any particular computer or other apparatus. Various general-purpose systems may be used with programs in accordance with the teachings herein, or it may prove convenient to construct more specialized apparatus to perform the required method steps. The required structure for a variety of these systems will appear from the description below. It will be appreciated that a variety of programming languages may be used to implement the teachings of the invention as described herein.

The figures and the following description describe certain embodiments by way of illustration only. One skilled in the art will readily recognize from the following description that alternative embodiments of the structures and methods illustrated herein may be employed without departing from the principles described herein. Reference will now be made in detail to several embodiments, examples of which are illustrated in the accompanying figures. It is noted that wherever practicable similar or like reference numbers may be used in the figures to indicate similar or like functionality.

The foregoing description of the embodiments of the present invention has been presented for the purposes of illustration and description. It is not intended to be exhaustive or to limit the present invention to the precise form disclosed. Many modifications and variations are possible in light of the above teaching. It is intended that the scope of the present invention be limited not by this detailed description, but rather by the claims of this application. As will be understood by those familiar with the art, the present invention may be embodied in other specific forms without departing from the spirit or essential characteristics thereof. Likewise, the particular naming and division of the modules, routines, features, attributes, methodologies and other aspects are not mandatory or significant, and the mechanisms that implement the present invention or its features may have different names, divisions and/or formats.

Furthermore, as will be apparent to one of ordinary skill in the relevant art, the modules, routines, features, attributes, methodologies and other aspects of the present invention can be implemented as software, hardware, firmware or any combination of the three. Also, wherever a component, an example of which is a module, of the present invention is implemented as software, the component can be implemented as a standalone program, as part of a larger program, as a plurality of separate programs, as a statically or dynamically linked library, as a kernel loadable module, as a device driver, and/or in every and any other way known now or in the future to those of ordinary skill in the art of computer programming.

Additionally, the present invention is in no way limited to implementation in any specific programming language, or for any specific operating system or environment. Accordingly, the disclosure of the present invention is intended to be illustrative, but not limiting, of the scope of the present invention, which is set forth in the following claims.

One or more elements or aspects or steps, or any portion(s) thereof, from one or more of any of the systems and methods described herein may be combined with one or more elements or aspects or steps, or any portion(s) thereof, from one or more of any of the other systems and methods described herein and combinations thereof, to form one or more additional implementations and/or claims of the present disclosure.

One or more of the components, steps, features, and/or functions illustrated in the figures may be rearranged and/or combined into a single component, block, feature or function or embodied in several components, steps, or functions. Additional elements, components, steps, and/or functions may also be added without departing from the disclosure. The apparatus, devices, and/or components illustrated in the Figures may be configured to perform one or more of the methods, features, or steps described in the Figures. The algorithms described herein may also be efficiently implemented in software and/or embedded in hardware.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description are presented in terms of algorithms and symbolic representations of operations on data bits within a computer memory. These algorithmic descriptions and representations are the methods used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared or otherwise manipulated. It has proven convenient at times, principally for reasons of common usage, to refer to these signals as bits, values, elements, symbols, characters, terms, numbers or the like.

It should be borne in mind, however, that all of these and similar terms are to be associated with the appropriate physical quantities and are merely convenient labels applied to these quantities. Unless specifically stated otherwise as apparent from the following disclosure, it is appreciated that throughout the disclosure terms such as “processing,” “computing,” “calculating,” “determining,” “displaying” or the like, refer to the action and processes of a computer system, or similar electronic computing device, that manipulates and transforms data represented as physical (electronic) quantities within the computer system's registers and memories into other data similarly represented as physical quantities within the computer system's memories or registers or other such information storage, transmission or display.

Finally, the algorithms and displays presented herein are not inherently related to any particular computer or other apparatus. Various general-purpose systems may be used with programs in accordance with the teachings herein, or it may prove convenient to construct more specialized apparatus to perform the required method steps. The required structure for a variety of these systems will appear from the description below. It will be appreciated that a variety of programming languages may be used to implement the teachings of the invention as described herein.

The figures and the following description describe certain embodiments by way of illustration only. One skilled in the art will readily recognize from the following description that alternative embodiments of the structures and methods illustrated herein may be employed without departing from the principles described herein. Reference will now be made in detail to several embodiments, examples of which are illustrated in the accompanying figures. It is noted that wherever practicable similar or like reference numbers may be used in the figures to indicate similar or like functionality.

The foregoing description of the embodiments of the present invention has been presented for the purposes of illustration and description. It is not intended to be exhaustive or to limit the present invention to the precise form disclosed. Many modifications and variations are possible in light of the above teaching. It is intended that the scope of the present invention be limited not by this detailed description, but rather by the claims of this application. As will be understood by those familiar with the art, the present invention may be embodied in other specific forms without departing from the spirit or essential characteristics thereof. Likewise, the particular naming and division of the modules, routines, features, attributes, methodologies and other aspects are not mandatory or significant, and the mechanisms that implement the present invention or its features may have different names, divisions and/or formats.

Furthermore, as will be apparent to one of ordinary skill in the relevant art, the modules, routines, features, attributes, methodologies and other aspects of the present invention can be implemented as software, hardware, firmware or any combination of the three. Also, wherever a component, an example of which is a module, of the present invention is implemented as software, the component can be implemented as a standalone program, as part of a larger program, as a plurality of separate programs, as a statically or dynamically linked library, as a kernel loadable module, as a device driver, and/or in every and any other way known now or in the future to those of ordinary skill in the art of computer programming.

Additionally, the present invention is in no way limited to implementation in any specific programming language, or for any specific operating system or environment. Accordingly, the disclosure of the present invention is intended to be illustrative, but not limiting, of the scope of the present invention, which is set forth in the following claims.

It is understood that the specific order or hierarchy of blocks in the processes/flowcharts disclosed is an illustration of example approaches. Based upon design preferences, it is understood that the specific order or hierarchy of blocks in the processes/flowcharts may be rearranged. Further, some blocks may be combined or omitted. The accompanying method claims present elements of the various blocks in a sample order and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

1. A method for providing a personalized workout session, the method comprising:
collecting heart rate data of a user during a calibration workout session;
determining a plurality of personalized heart rate zones for the user based on the collected heart rate data; and
providing, to an exercise equipment, a workout session having a plurality of workout segments, wherein each workout segment has a target heart rate zone that is associated with one of the plurality of personalized heart rate zones.

2. The method of claim 1, wherein collecting heart rate data comprises using a wearable device having a heart rate sensor to collect the user's heart rate data.

3. The method of claim 1, wherein the workout session comprises a pre-recorded workout video or a live-stream of a workout session.

4. The method of claim 1, further comprising:
collecting a current heart rate of the user while the user is performing the provided workout session;
determining the target heart rate zone based on a current workout segment of the user within the workout session;
comparing the user's current heart rate to the determined target heart rate zone to generate a comparison; and
delivering an instruction to the exercise equipment based at least on the comparison of the current heart rate of the user's and the target heart rate zone.

5. The method of claim 4, wherein the instruction comprises instructions requesting the user to change one or more operating parameters of the exercise equipment.

6. The method of claim 4, wherein the instruction comprises instruction to the exercise equipment to automatically change one or more operating parameters of the exercise equipment.

7. The method of claim 4, wherein the one or more operating parameters comprise of an operating parameter selected from a group consisting of resistance, inclination, tilt, and playback audio.

8. An exercise system comprising:
an exercise equipment having a sensor configured to determine a plurality of performance metrics;
a memory; and
one or more processors coupled to the memory, the one or more processors configured to:
collecting heart rate data while a user is performing a workout session;
determining a target heart rate zone based on a current workout segment of the user within the workout session;
comparing a current heart rate of the user to the determined target heart rate zone to generate a comparison; and
adjusting one or more operating parameter of the exercise equipment based at least on the plurality of performance metrics from a crank sensor and the comparison of the current heart rate of the user and the target heart rate zone.

9. The exercise system of claim 8, further comprising delivering an instruction to the exercise equipment based at least on the comparison of the current heart rate of the user and the target heart rate zone.

10. The exercise system of claim 8, wherein adjusting one or more operating parameter of the exercise equipment comprises presenting instructions to the user to change one or more operating parameters of the exercise equipment.

11. The exercise system of claim 8, wherein adjusting one or more operating parameter of the exercise equipment comprises automatically adjusting one or more operating parameters of the exercise equipment.

12. The exercise system of claim 11, wherein the one or more operating parameters comprise of an operating parameter selected from a group consisting of resistance, inclination, tilt, and playback audio.

13. The exercise system of claim 8, wherein collecting heart rate data comprises using a wearable device having a heart rate sensor to collect the user's heart rate data.

14. A method for providing a personalized workout session, the method comprising:
collect heart rate data while a user is performing a workout session;
determine a target heart rate zone based on a current workout segment of the user within the workout session;
compare a current heart rate of the user to the determined target heart rate zone to generate a comparison; and
adjust one or more operating parameter of exercise equipment based at least on a plurality of performance metrics from a crank sensor and the comparison of the current heart rate of the user and the target heart rate zone.

15. The method of claim 14, further comprising delivering an instruction to the exercise equipment based at least on the comparison of the current heart rate of the user and the target heart rate zone.

16. The method of claim 14, wherein adjusting one or more operating parameter of the exercise equipment comprises presenting instructions to the user to change one or more operating parameters of the exercise equipment.

17. The method of claim 14, wherein adjusting one or more operating parameter of the exercise equipment comprises automatically adjusting one or more operating parameters of the exercise equipment.

18. The method of claim 17, wherein the one or more operating parameters comprise of an operating parameter selected from a group consisting of resistance, inclination, tilt, and playback audio.

19. The method of claim 14, wherein collecting heart rate data comprises using a wearable device having a heart rate sensor to collect the user's heart rate data.

20. The method of claim 14, wherein the workout session comprises a pre-recorded workout video or a live-stream of a workout session.
